(19) United States
(12) Patent Application Publication
(10) Pub. No.: US 2012/0219914 A1
(43) Pub. Date: Aug. 30, 2012

(54) DRAWING APPARATUS, DRAWING METHOD AND METHOD OF MANUFACTURING ARTICLE

(75) Inventor: Masato Muraki, Inagi-shi (JP)

(73) Assignee: CANON KABUSHIKI KAISHA, Tokyo (JP)

(21) Appl. No.: 13/402,071

(22) Filed: Feb. 22, 2012

(30) Foreign Application Priority Data
Feb. 25, 2011 (JP) 2011-040270

(51) Int. Cl. G03F 7/20; H01J 3/26

(52) U.S. Cl. 430/296; 250/396 R

(57) ABSTRACT

A drawing apparatus for drawing on a substrate by a plurality of charged particle beams includes: an aperture array, a blanker array, a scanning mechanism, and a controller. The aperture array specifies the dimension of each of the plurality of charged particle beams on the substrate. The blanker array carries out blanking of the plurality of charged particle beams independently. The scanning mechanism performs a relative scanning between the plurality of charged particle beams and the substrate in each of the first direction and a second direction which cross each other. The controller controls the blanker array at a predetermined pitch on the substrate. The dimension and the pitch are smaller in one of the first direction and the second direction than in the other.

### BACKGROUND OF THE INVENTION

1. Field of the Invention

Embodiments of the present invention relate to a drawing apparatus and method that perform drawing on a substrate with a plurality of charged particle beams.

2. Description of the Related Art

In photolithography, as the minimum pattern dimension comes close to the wavelength of a light source, a substrate may be exposed to a pattern which is different from that intended to be due to unintended interaction (i.e., interference) of light. As the intended pattern becomes finer and interaction of light becomes more complicated, even the light proximity effect correction is not enough to sufficiently correct the pattern. In order to solve such a problem, a device design rule in which the width of a pattern is constant and the longitudinal direction of the pattern is limited (hereinafter, “1D-layout”) and a processing method therefor have been proposed (Axelrad, Valery and another, “16 nm with 193 nm Immersion Lithography and Double Exposure” Proc. of SPIE, 2010, Vol. 7641, 764109-1).

The related art processing method will be described with reference to FIG. 10. This method relates to a photolithographic process using an immersion exposure device (light source wavelength: 193 nm) with a gate cell of 22-nm generation SRAM as an object. The steps will be described below.

Step 1: exposing a line and space pattern of half pitch (44 nm)

Step 2: applying anisotropic etching directly (or after processing a base and isotopically forming a layer on the entire base surface) to a pattern formed by development, whereby a layer is left on sidewalls, i.e., an outline, of the pattern

A line and space hard mask of half pitch (22 nm) is thus obtained. This is a double patterning method using the sidewalls.

Step 3: applying resist and exposing a hole pattern for cutting

Step 4: reducing an exposed hole pattern area by a chemical process

Step 5: carrying out anisotropic etching again to obtain a hard mask of desired gate cell pattern

The method described above requires the double patterning method even if an immersion exposure device is used and has difficulty in exposing the hole pattern for cutting; it is therefore necessary to carry out such a pattern reduction process as Step 4. The method requires a larger numbers of masks and processes and thereby the photolithographic process is high in cost and low in reliability.

### SUMMARY OF THE INVENTION

One disclosed aspect of the embodiments provides, for example, a drawing apparatus advantages in terms of reliability and throughput with which drawing is performed under a design rule. An aspect of the embodiments is a drawing apparatus which performs drawing on a substrate with a plurality of charged particle beams. The apparatus includes: an aperture array which defines a dimension of each of the plurality of charged particle beams on the substrate; a blanker array configured to perform blanking of the plurality of charged particle beams; a scanning mechanism configured to perform a relative scanning between the plurality of charged particle beams and the substrate in each of the first direction and a second direction which cross each other; and a controller configured to control the blanker array at a predetermined pitch on the substrate, wherein the dimension and the pitch are smaller in one of the first direction and the second direction than in the other.

According to one aspect of the embodiments, a drawing apparatus which has advantages in reliability and throughput in drawing a pattern under the above-described design rule is provided.

Further features of the embodiments will become apparent from the following description of exemplary embodiments with reference to the attached drawings.

### BRIEF DESCRIPTION OF THE DRAWINGS

FIG. 1 illustrates a configuration of a drawing apparatus.

FIG. 2 illustrates a configuration of a blanker array.

FIG. 3 illustrates a raster scanning drawing method.

FIG. 4 illustrates an arrangement and scanning of an electron beam subarray on a substrate.

FIG. 5 illustrates scanning loci of electron beams on the substrate.

FIG. 6 illustrates a positional relationship among a plurality of stripe drawing areas SA.

FIG. 7 illustrates a method of drawing a 1D-layout cut pattern.

FIG. 8 illustrates a comparison between a drawing apparatus according to an embodiment and a drawing apparatus of a related art.

FIG. 9 illustrates a method of drawing a 1D-layout intermittent linear pattern.

FIG. 10 illustrates a prior art design rule and a processing method.

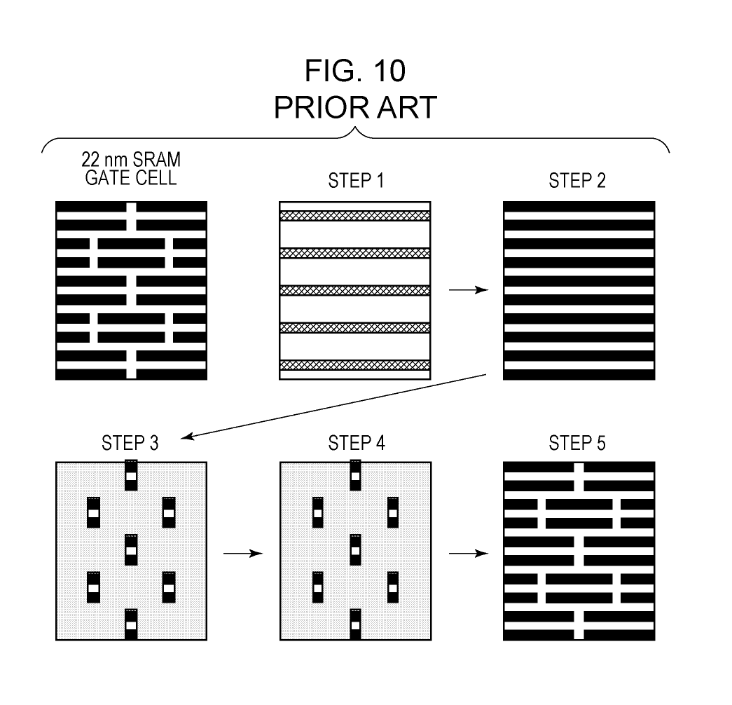

### DESCRIPTION OF THE EMBODIMENTS

Hereinafter, embodiments will be described with reference to accompanying drawings. In the drawings, generally, the same components are denoted by the same reference numerals and repeated description thereof will be omitted.

### First Embodiment

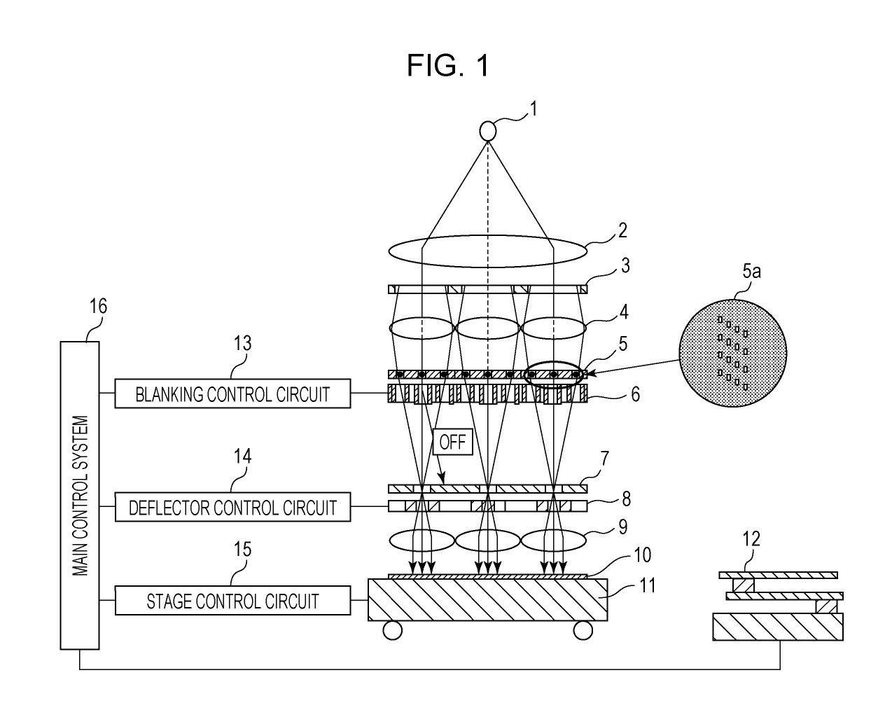

FIG. 1 illustrates a configuration of a drawing apparatus. In FIG. 1, the reference numeral 1 denotes an electron source, which may be a thermoelectron electron source including LaB6 or BaO/W (i.e., a dispenser cathode) as an electron emission material. The reference numeral 2 denotes a collimating lens which may be an electrostatic lens converging electron beams with the application of an electric field. The electron beams emitted from the electron source 1 become substantially parallel to one another at the collimating lens 2. The drawing apparatuses according to the first and second embodiments draw a pattern on a substrate with a plurality of electron beams. However, charged particle beams, such as ion lines, may be used in place of the electron beams. The drawing apparatuses according to the first and second embodiments may be generalized in drawing apparatuses which draw a pattern on a substrate with a plurality of charged particle beams.

The reference numeral 3 denotes an aperture array (i.e., an aperture array member) which has apertures arranged in two dimensions. The reference numeral 4 denotes a condenser lens array which has electrostatic condenser lenses of the same in optical power arranged in two dimensions. The reference numeral 5 denotes a pattern aperture array (i.e., an aperture array member) which has a pattern aperture array (i.e., a subarray) which specifies (i.e., determines) the shape of the electron beams. Each of the pattern apertures corresponds to each of the condenser lenses. The reference numeral 5a denotes the shape of the subarray seen from above.

The substantially parallel electron beams output from the collimating lens 2 are divided into a plurality of electron beams at the aperture array 3. The divided electron beams illuminate the subarray of the corresponding pattern aperture array 5 via the corresponding condenser lens of the condenser lens array 4. Here, the aperture array 3 has a function to specify a range of the illumination.

The reference numeral 6 denotes a blanker array which has electrostatic blankers (i.e., electrode pairs) each of which is arranged to correspond to each of the condenser lenses. Each of the blankers may be driven independently. The reference numeral 7 denotes a blanking aperture array which has blanking apertures (i.e., apertures) each of which is arranged to correspond to each of the condenser lenses. The reference numeral 8 denotes a deflector array which has deflectors each of which is arranged to correspond to each of the condenser lenses. The deflectors deflect the electron beams in a predetermined direction. The reference numeral 9 denotes an objective lens array which has electrostatic objective lenses each of which is arranged to correspond to each of the condenser lenses. A wafer (i.e., a substrate) 10 is provided on which drawing (i.e., exposure) is carried out. Here, components denoted by reference numerals 1 to 7 and 9 constitute a projection system.

The electron beams from each subarray of the pattern aperture array 5 illuminated with the electron beams are converged into the dimension of 1/100 via the corresponding blanker, blanking apertures, deflector and objective lens and are projected on the wafer 10. Here, the surface of the subarray on which the pattern apertures are arranged is an object surface and an upper surface of the wafer 10 is an imaging surface.

Whether the electron beams from the subarray of the pattern aperture array 5 illuminated with the electron beams are blocked by the blanking apertures by controlling the corresponding blankers is switched, i.e., whether the electron beams enter the wafer is switched. At the same time, the electron beams which enter the wafer are made to scan the wafer by the deflector array 8 with the same deflection amount.

The electron source 1 is imaged on the blanking apertures via the collimating lens 2 and the condenser lens. The dimension of the image is defined to be larger than the aperture dimension of the blanking apertures. For this reason, the semiangle (i.e., the half width) of the electron beams on the wafer is defined by the aperture dimension of the blanking apertures. Since the apertures of the blanking apertures are arranged at an object focal point position of the corresponding objective lens, the principal rays of a plurality of electron beams from a plurality of pattern apertures of the subarray enter the wafer in a substantially vertical direction. For this reason, even if the upper surface of the wafer 10 is moved vertically, displacement of the electron beams in the horizontal plane is very small.

The reference numeral 11 denotes an X-Y stage (also called “stage”) on which the wafer 10 is held. The X-Y stage is movable on an X-Y plane (i.e., the horizontal plane) which is perpendicular to the optical axis. The stage includes an electrostatic chuck (not illustrated) which holds (i.e., sucks) the wafer 10 and a detector (not illustrated) which has an aperture pattern through which the electron beams enter and detects positions of the electron beams. The reference numeral 12 denotes a conveyance mechanism which conveys the wafer 10 and delivers and receives the wafer 10 between the stage 11.

The blanking control circuit 13 is a control circuit which independently controls a plurality of blankers constituting the blanker array 6. The deflector control circuit 14 is a control circuit which controls, with a common signal, a plurality of deflectors constituting the deflector array 8. The main control system 16 is a control circuit for controlling positional alignment of the stage 11 in cooperation with a stage control circuit 15 and with an unillustrated laser interferometer which measures the position of the stage. The main control system 16 controls a plurality of control circuit described above and collectively controls the drawing apparatus. Although the control unit of the drawing apparatus is constituted by the control circuits 13 to 15 and the main control system 16 in the present embodiment, this configuration is illustrative only and may be changed arbitrarily.

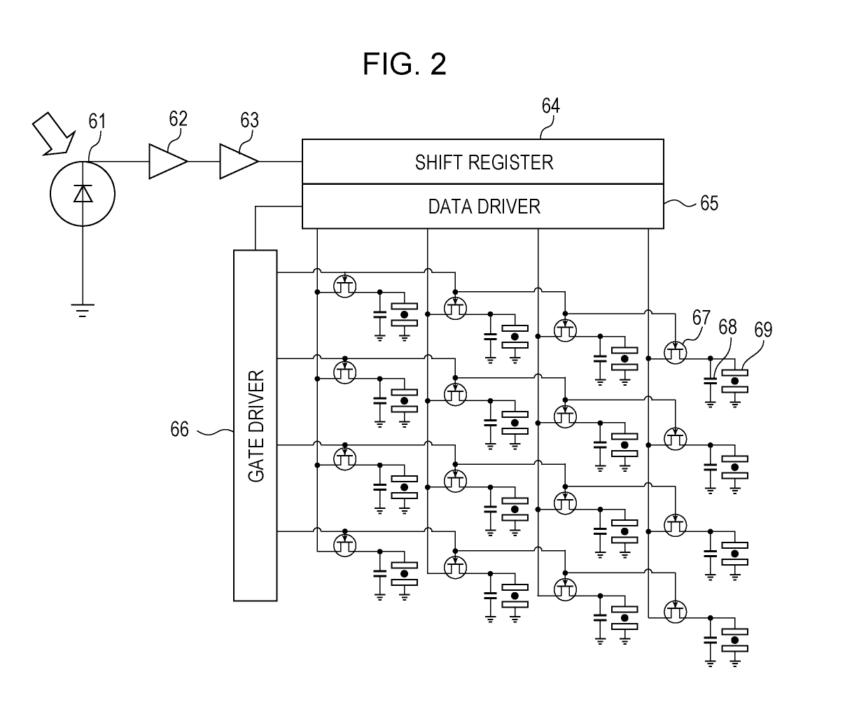

FIG. 2 illustrates a configuration of the blanker array 6. Control signals from the blanking control circuit 13 is supplied to the blanker array 6 via an optical fiber for optical communication (not illustrated). Control signals of a plurality of blankers are transmitted from the fiber. The control signals transmitted from each fiber correspond to each subarray. A light signal from the optical fiber for optical communication is received by a photo diode 61; current-voltage conversion is carried out in a transfer impedance amplifier 62; and amplitude is adjusted in a limiting amplifier 63. An amplitude-adjusted signal is input in a shift register 64, where a serial signal is converted into a parallel signal. FETs 67 are disposed at intersections of gate electrode line which run in the transverse direction and source electrode lines which run in the vertical direction. Buses are connected to a gate and a source of each FET 67. A blanker electrode 69 and a capacitor 68 are connected to a drain of each FET 67. Opposite sides of these capacitive elements are connected to a common electrode. When voltage is applied to one row of the gate electrode lines, all the FETs connected to that gate electrode line are turned on and then current flows between the sources and the drains. The voltage applied to the source electrode line at that time is applied to the blanker electrode 69 and electric charge corresponding to the voltage is accumulated (i.e., charged) in the capacitor 68. The gate electrode line is switched after each row is charged and the voltage is applied to the next row. Then, the FETs of the first row lose the gate voltage and are turned off. Although the blanker electrodes 69 of the first row lose voltage from the source electrode line, the blanker electrodes 69 may maintain necessary voltage until the voltage is applied the next time to the gate electrode line by the electric charge accumulated in the capacitors 68. In the active matrix driving system using the FET as a switch, the voltage may be applied to multiple FETs in parallel by the gate electrode line. Thus, it is possible to increase the number of the blankers with a smaller amount of wiring.

In the example of FIG. 2, the blankers are arranged in four rows and four columns. The parallel signals from the shift register 64 are applied to a source electrode of the FET as voltage via a data driver 65 and the source electrode. In cooperation with this, one row of the FETs is turned on by the voltage applied from the gate driver 66, and thereby a row of corresponding blankers are controlled. Such an operation is repeated for the entire row and thus the blankers arranged in four rows and four columns are controlled.

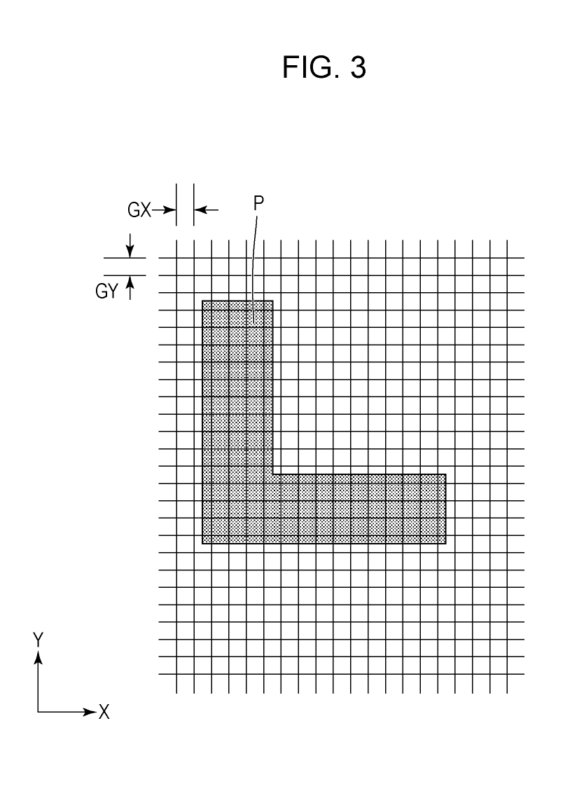

With reference to FIG. 3, a raster scanning drawing method according to the present embodiment will be described. Illumination or non-illumination of the electron beams on the substrate is controlled by the blanker array 6 in accordance with the drawing pattern P while the electron beams are scanned on the scanning grids on the wafer 10 determined by the deflection of the deflector array 8 and the position of the stage 11. Here, the scanning grids are arranged at a pitch GX (i.e., a first interval) in the X direction and at a pitch GY (i.e., a second interval) in the Y direction as illustrated in FIG. 3. Illumination or non-illumination of the electron beam is assigned to intersections of the vertical line and the horizontal line (i.e., grid points) in FIG. 3.

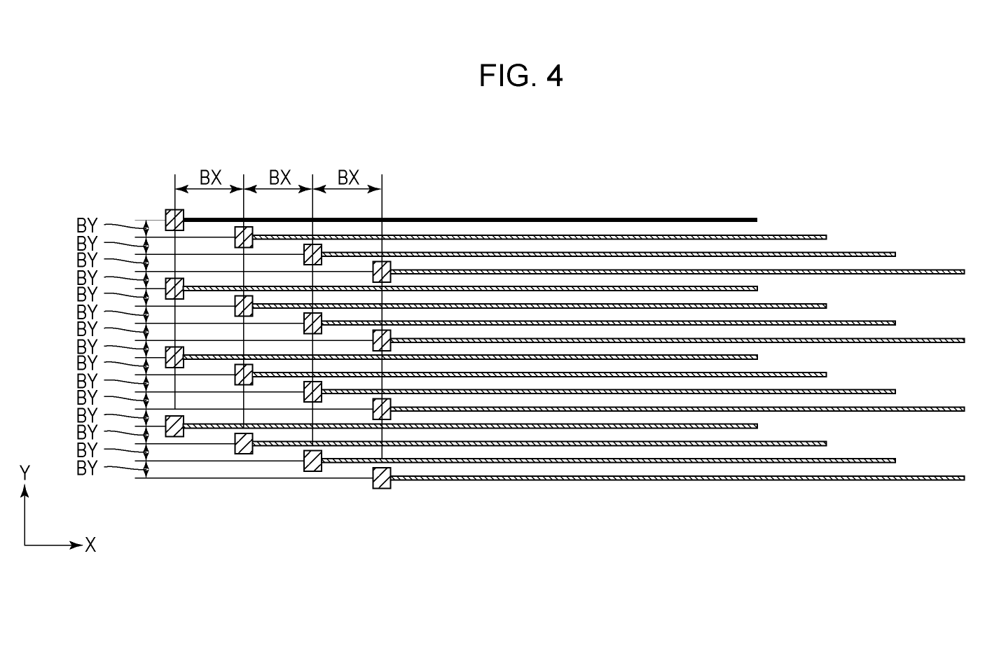

FIG. 4 illustrates an arrangement and scanning of the electron beam subarray on the wafer. As illustrated in FIG. 4, the pattern apertures of the subarray are projected on the wafer at the pitch BX in the X direction and at the pitch BY in the Y direction. The dimension of each pattern aperture on the wafer is at the pitch PX in the X direction and at the pitch PY in the Y direction. The pattern apertures are reduced to 1/100 and projected on the wafer; thus, the actual dimension of the pattern apertures are 100 times the dimension projected on the wafer. An image of the pattern apertures (i.e., the electron beams) are deflected in the X direction by the deflector array 8 and are used to scan the wafer. At the same time, the stage 11 is continuously moved (i.e., scanned) in the Y direction. The electron beams are deflected in the Y direction by the deflector array 8 such that the each of the electron beams is stationary in the Y direction on the wafer 10. The deflector array 8 which deflects the charged particle beam projected by the projection system in at least the X direction (i.e., the first direction) and the stage 11 which holds the substrate and is movable in the Y direction (i.e., the second direction perpendicular to the first direction) are included in the scanning unit. Here, the scanning unit carries out relative scanning between a plurality of charged particle beams and the substrate in the X direction and the Y direction.

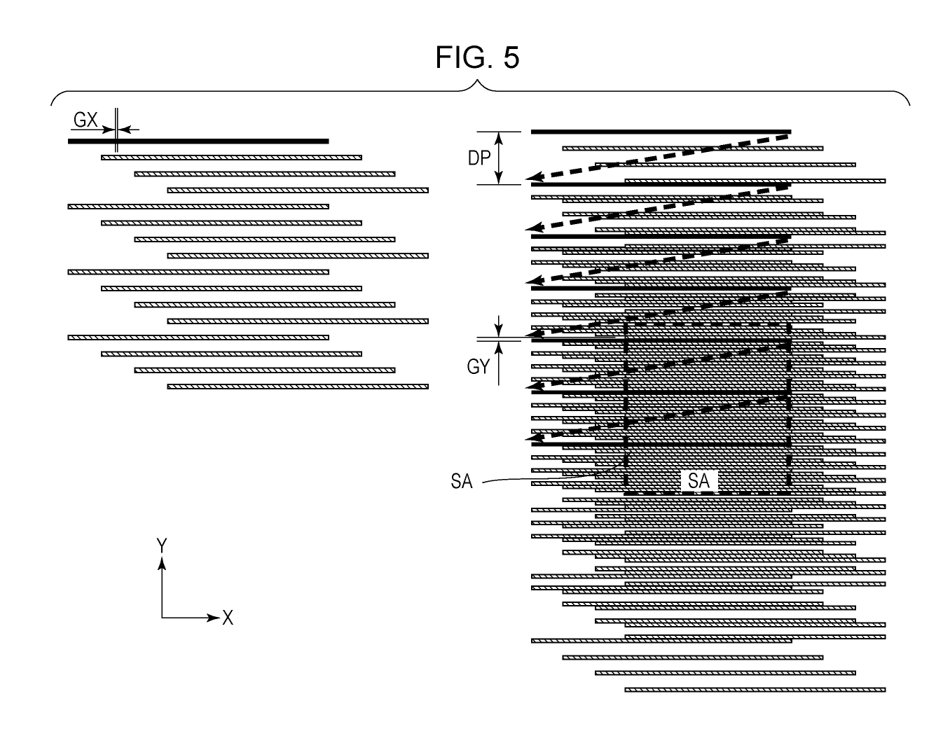

FIG. 5 illustrates scanning loci of electron beams on the wafer. In FIG. 5, the left half illustrates scanning loci of each electron beam of the subarray in the X direction. Here, illumination or non-illumination of each electron beam is controlled for each grid point specified by the grid pitch GX. For ease of description, the locus of the topmost electron beam is illustrated by thick black line. In FIG. 5, the right half illustrates loci formed by repeating the scanning of each electron beam in the X direction, flyback in the deflection width DP in the Y direction illustrated by dashed line arrows, and then scanning of the electron beam in the X direction. It is recognized that, in an area surrounded by a thick dashed line, a stripe drawing area SA of the stripe width SW is filled with the grid pitches GY. That is, the stripe drawing area SA may be drawn by a constant-speed continuous movement of the stage 11. The conditions thereof are to satisfy the following formulae:

N2=K×L+1 (K and L are natural numbers) (1);

BY=GY×K (2);

and

DP=(K×L+1)×GY=N2×GY (3),

where the number of beams of the subarray is N×N.

Under these conditions, when the beam interval BY in the Y direction is decided as the formula (2) by K which satisfies the formula (1), a fine pattern may be drawn by the finer scanning grid pitch GY, without depending on the finer apertures and blanker intervals that have limitation in manufacture. When the deflection width DP in the Y direction is decided by the formula (3), drawing may be carried out at the grid pitch GY anywhere in the stripe drawing area SA below the starting points of the black arrows illustrated in FIG. 5. It is therefore possible to draw a fine pattern reliably by continuously moving (i.e., scanning) the stage in one direction.

In the present embodiment, N=4, K=5, L=3, GY=5 nm, BY=25 nm, DP=80 nm and SW=2 micrometers. Since the stripe width SW is always smaller than the deflection width of each electron beam, it is desired to satisfy N×BY>BX as long as the pitch between the blankers may be accepted in manufacture. Thus, the deflection area which is not used for drawing may be reduced and it becomes more advantageous in production capacity.

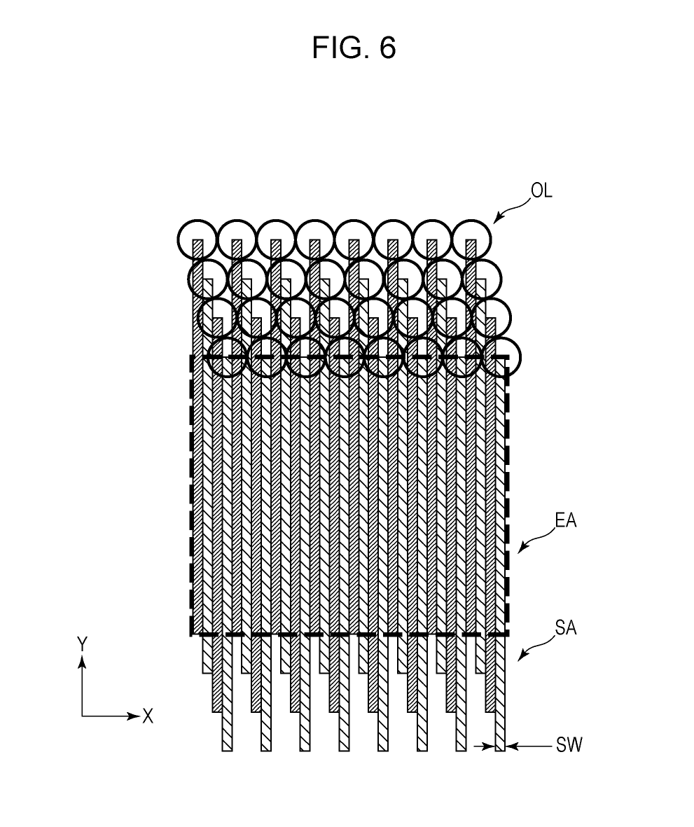

FIG. 6 illustrates a positional relationship among a plurality of stripe drawing areas SA for each subarray (or object lens). In an objective lens array 9, objective lenses are arranged in one dimension at the 144-micrometer pitches in the X direction, and the next row of the objective lenses is displaced by 2 micrometers in the X direction such that the stripe drawing areas SA adjoin one another. For ease of illustration, the objective lens array has objective lenses arranged in four rows and eight columns. Actually, however, the objective lens array may have objective lenses arranged, for example, in 72 rows and 180 columns (including a total of 12960 objective lenses). With this configuration, drawing may be carried out in the exposed area EA on the wafer 10 by making the stage 11 be continuously moved (i.e., scanned) in one way along the Y direction.

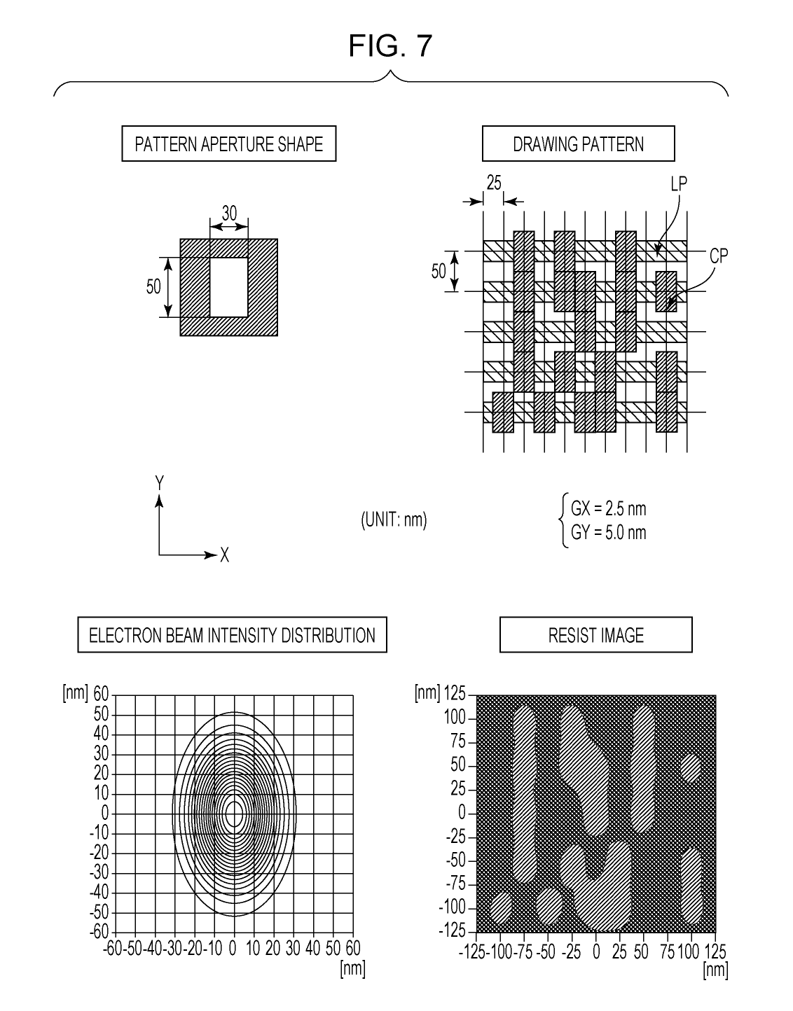

FIG. 7 illustrates a method of drawing a 1D-layout cut pattern. In the drawing of a cut pattern, as illustrated in the “drawing pattern” in FIG. 7, linear patterns LP arranged in the Y direction at predetermined intervals (e.g., at regular intervals) and extending along a straight line in the X direction are formed previously. In particular, the line patterns LP are formed at 50-nm pitches in the Y direction and with the Y direction width of 25 nm. Cut patterns CP for cutting the linear patterns LP are drawn. Therefore, the dimension of the cut pattern CP needs to be larger in the Y direction than in the X direction and the dimensional accuracy may be lower in the Y direction than in the X direction. In addition, the drawing positional accuracy of the cut pattern CP may be lower in the Y direction than in the X direction.

Then, as illustrated in “pattern aperture shape” in FIG. 7, the pattern aperture of the pattern aperture array has a rectangular shape with the horizontal width PX of 30 nm and the vertical width PY of 50 nm in the wafer equivalent. As illustrated in “electron beam intensity distribution” in FIG. 7, an image of the pattern aperture on the wafer is larger in the Y direction than in the X direction.

As stated above, since the drawing positional accuracy of the cut pattern CP may be lower in the Y direction than in the X direction, the scanning grids are arranged at the pitch of GX=2.5 nm and C=5.0 nm. That is, the dimensional relationship between the cut pattern CP in the X direction (i.e., the first direction) and in the Y direction (i.e., the second direction) and the dimensional relationship between the pitch GX (i.e., the first interval) and the pitch GX (i.e., the second interval) of the scanning grids are equivalent to each other. The drawing result is illustrated as “resist image” in FIG. 7. It is recognized that the pattern to be separated has been sufficiently separated by the cut pattern and that drawing has been carried out at the level at which no problem will be caused in subsequent processes.

In the present embodiment, it is necessary to make the X-Y axis of the drawing apparatus and the orientation of the wafer (i.e., the pattern drawn on the wafer) be consistent with each other. Therefore, the wafer 10 is transferred onto the stage 11 via a conveyance mechanism 12 which conveys the wafer 10 to the stage 11, such that the consistency described above is achieved. For example, a controller (this controller may be the main control system 16) may control at least one of the operation of the conveyance mechanism 12 and the operation of the stage 11 such that the wafer 10 is held by the stage 11 in a manner that the X direction (i.e., the first direction) or the Y direction (i.e., the second direction) of the drawing apparatus and the orientation of the wafer 10 are consistent with each other.

Since the grid pitch is of GX=2.5 nm and GY=5.0 nm and the cut pattern CP is rectangular in shape of PX=30 nm and PY=50 nm, information about the pattern may be generated for each grid point of the grid pitch. Therefore, pattern information may be easily handled and the load in converting the pattern information into drawing information on the grid point basis is reduced.

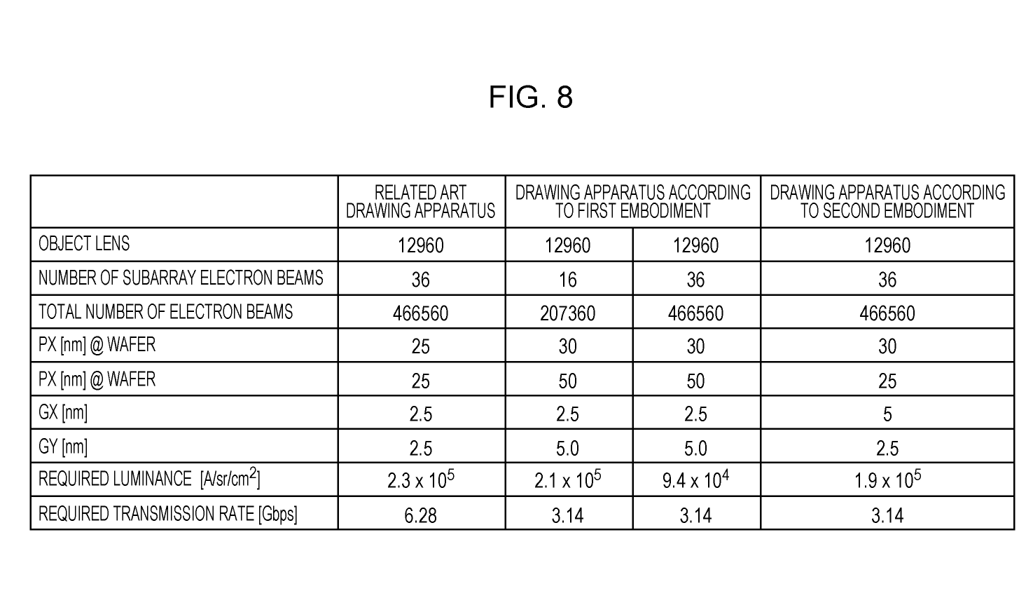

FIG. 8 is a diagram (i.e., a table) illustrating a comparison between the drawing apparatus according to the present embodiment for 1D-layout cut pattern drawing and the related art drawing apparatus. The conditions for the comparison are as follows:

1) the drawing apparatus is a 22-nm generation device;
2) resist sensitivity is 20 microC/cm2;
3) production capacity is twenty 300-mm wafers may be drawn per hour; and
4) the number of objective lenses is 12960.

In the related art drawing apparatus, the aperture dimension (PX, PY) of the pattern aperture array and the scanning grid pitch (GX, GY) of the scanning grid are the same in the X direction and in the Y direction in order to support any pattern. As a result, the number of the electron beams of the subarray is 36 and the total number of the electron beams is 466560. Luminance required for the electron source is 2.3×105 (A/sr/cm2); such high luminance involves high cathode temperature of the dispenser cathode and thus has a short life. The transmission rate required for the communication optical fiber is 6.38 (GBPS). Since generation of heat in the transfer impedance amplifier 62, the limiting amplifier 63 and the shift register 64 becomes large in proportion to the increase in the transmission rate, the related art drawing apparatus is disadvantageous in reliability in operation of the blanker array 6.

In a case in which the number of the electron beams of the subarray is 16, since the drawing apparatus of the present embodiment may achieve the same production capacity as that of the related art drawing apparatus with substantially half the total number of the electron beams, the drawing apparatus of one embodiment only requires substantially half the transmission rate and lower luminance necessary for the electron source. If the total number of the electron beams is the same, the same production capacity may be achieved with substantially half the transmission rate and with lower than half the luminance of the electron source. According to one embodiment, a drawing apparatus which has advantages in reliability and throughput in drawing the 1D-layout cut pattern may be provided.

### Second Embodiment

The present embodiment relates to a drawing apparatus which draws a 1D-layout intermittent linear pattern. The present embodiment has the same configuration as that of the first embodiment except for the pattern aperture and the scanning grid.

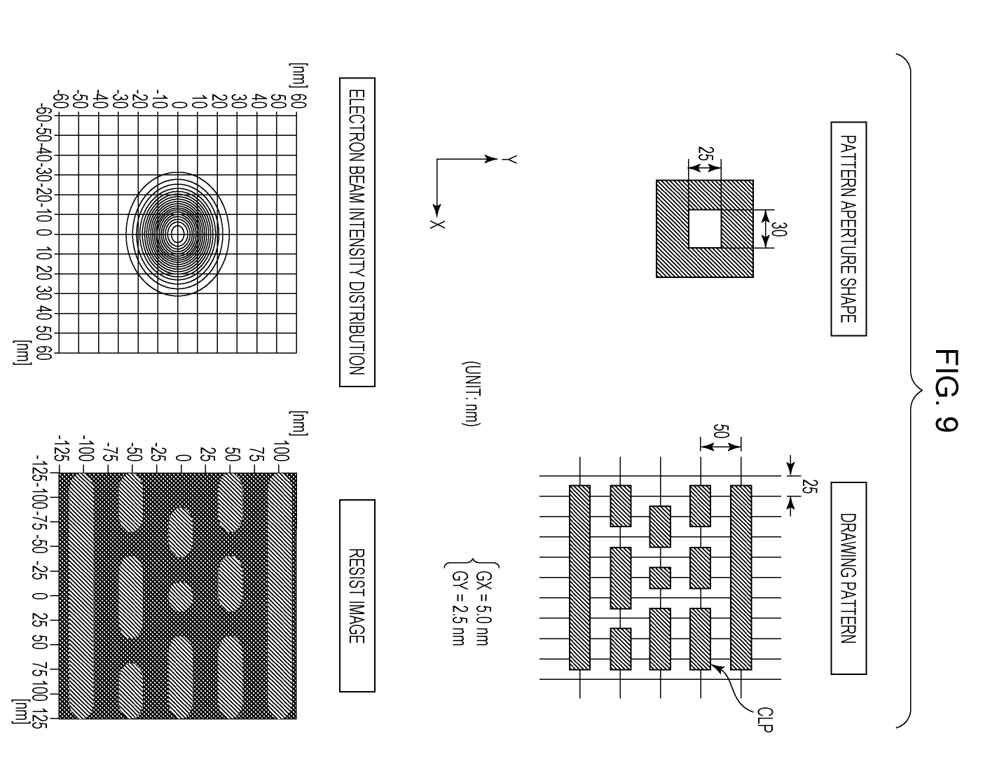

FIG. 9 illustrates a method of drawing a 1D-layout intermittent linear pattern. As illustrated in “drawing pattern” in FIG. 9, the present embodiment draws intermittent linear patterns CLP arranged in the Y direction at predetermined intervals (e.g., regular intervals) and each extending along a straight line in the X direction. The intermittent linear patterns CLP are arranged at the pitch of 50 nm and the line width of 25 nm in the Y direction. In the intermittent linear pattern CLP, uniformity in the line width in the Y direction is important and the shapes of ends of the linear patterns in the X direction are less important. Therefore, the dimensional accuracy of the intermittent linear pattern CLP needs to be higher in the Y direction than in the X direction. The drawing positional accuracy of the intermittent linear pattern CLP needs to be higher in the Y direction than in the X direction.

Then, as illustrated in “pattern aperture shape” in FIG. 9, the pattern aperture of the pattern aperture array has a rectangular shape with the horizontal width PX of 30 nm and the vertical width PY of 25 nm in the wafer equivalent. As illustrated in “electron beam intensity distribution” in FIG. 9, an image of the pattern aperture on the wafer is smaller in the Y direction than in the X direction. Thus, the dimensional accuracy of the intermittent linear pattern CLP is higher in the Y direction than in the X direction.

Since it is necessary that the drawing positional accuracy of the intermittent linear pattern CLP is higher in the Y direction than in the X direction, the scanning grid are arranged at the pitch of GX=5.0 nm and GY=2.5 nm. That is, the dimensional relationship between the intermittent linear pattern CP in the X direction (i.e., the first direction) and in the Y direction (i.e., the second direction) and the dimensional relationship between the pitch GX (i.e., the first interval) and the pitch GX (i.e., the second interval) of the scanning grids are equivalent to each other. The drawing result is illustrated as “resist image” in FIG. 9. It is recognized that the intermittent linear pattern has the constant line width in the Y direction and that drawing has been carried out at the level at which no problem will be caused in subsequent processes.

In the present embodiment, as in the first embodiment, it is necessary to make the X-Y axis of the drawing apparatus and the orientation of the wafer (i.e., the pattern drawn on the wafer) be coincident. Therefore, the wafer 10 is delivered and received between the stage 11 by a conveyance mechanism 12 which conveys the wafer 10 on the stage 11, such that the coincidence described above is achieved. It is only necessary that the control unit of, for example, the main control system 16 controls at least one of the operation of the conveyance mechanism 12 and the operation of the stage 11 such that the wafer 10 is held by the stage 11 in a manner that the X direction (i.e., the first direction) of the drawing apparatus or the Y direction (i.e., the second direction) and the orientation of the wafer 10 are coincident.

With reference to FIG. 8 again, the drawing apparatus according to the present embodiment which draws the 1D-layout intermittent linear pattern and the related art drawing apparatus will be compared. The conditions for the comparison are the same as those listed above. In the related art drawing apparatus, the dimension (PX, PY) of the pattern aperture of the pattern aperture array and the pitch (GX, GY) of the scanning grid are the same in the X direction and in the Y direction in order to support any pattern. As a result, the number of the electron beams of the subarray is 49 and the total number of the electron beams is 635040. Luminance required for the electron source is 2.3×105 (A/sr/cm2); such high luminance involves high cathode temperature of the dispenser cathode and thus has a short life. The transmission rate required for the communication optical fiber is 6.38 (GBPS). Since generation of heat in the transfer impedance amplifier 62, the limiting amplifier 63 and the shift register 64 becomes large in proportion to the increase in the transmission rate, the related art drawing apparatus is disadvantageous in reliability in operation of the blanker array 6.

The drawing apparatus of the present embodiment may achieve the same production capacity as that of the related art drawing apparatus with the same total number of electron beams but at substantially a half of the transmission rate and a lower luminance of the electron source. According to one embodiment, a drawing apparatus which has advantages in reliability and throughput in drawing the 1D-layout intermittent linear pattern may be provided.

### Third Embodiment

The method of manufacturing an article according to an embodiment is suitable to manufacture articles, including microdevices, such as semiconductor devices, and devices with fine structures. The manufacturing method may include a process to form a latent image pattern on a photosensitive agent applied to the substrate using the drawing apparatus described above (a process to draw on the substrate), and a process to develop the substrate on which the latent image pattern is formed in the process to draw on the substrate. The manufacturing method may include other known processes (e.g., oxidization, film formation, vapor deposition, doping, smoothing, etching, resist removing, dicing, bonding and packaging). The method of manufacturing an article according to the present embodiment is advantageous in at least one of performance, quality, productivity and production cost of the article as compared with those of the related art method.

While the present invention has been described with reference to exemplary embodiments, it is to be understood that the embodiments are not limited to the disclosed exemplary embodiments. The scope of the following claims is to be accorded the broadest interpretation so as to encompass all such modifications and equivalent structures and functions.

This application claims the benefit of Japanese Patent Application No. 2011-040270 filed Feb. 25, 2011, which is hereby incorporated by reference herein in its entirety.

What is claimed is:

1. A drawing apparatus which performs drawing on a substrate with a plurality of charged particle beams, the apparatus comprising:
an aperture array which defines a dimension of each of the plurality of charged particle beams on the substrate;
a blanker array configured to perform blanking of the plurality of charged particle beams;
a scanning mechanism configured to perform a relative scanning between the plurality of charged particle beams and the substrate in each of a first direction and a second direction which cross each other; and
a controller configured to control the blanker array at a predetermined pitch on the substrate,
wherein the dimension and the pitch are smaller in one of the first direction and the second direction than in the other.

2. The apparatus according to claim 1, wherein the apparatus is configured to draw, on the substrate, a cutting pattern for cutting a linear pattern extending in the first direction, the cutting pattern being smaller in the first direction than in the second direction.

3. The apparatus according to claim 1, wherein the apparatus is configured to draw, on the substrate, intermittent linear patterns extending in the first direction, each of which being larger in the first direction than in the second direction.

4. The apparatus according to claim 1, further comprising a stage configured to hold the substrate and a conveyance mechanism configured to convey the substrate onto the stage, wherein the controller is configured to control at least one of an operation of the stage and an operation of the conveyance mechanism such that one of the first direction and the second direction in which the dimension and the pitch are greater than the other is aligned with a longitudinal direction of a pattern to be drawn on the substrate.

5. The apparatus according to claim 1, wherein the scanning mechanism includes a deflector configured to deflect the charged particle beam on the substrate in the first direction and a stage configured to hold the substrate and to be movable in the second direction.

6. The apparatus according to claim 1, wherein the apparatus is configured to draw, on the substrate, a pattern on each of a straight line extending in the first direction, and a plurality of straight lines parallel with the straight line and arranged in the second direction at predetermined intervals.

7. A drawing method of performing drawing on a substrate with a plurality of charged particle beams, the method comprising:
projecting each of the plurality of charged particle beams onto the substrate at a predetermined dimension on the substrate;
performing a relative scanning between the plurality of charged particle beams and the substrate in each of a first direction and a second direction which cross each other; and
performing blanking of the plurality of charged particle beams at a predetermined pitch on the substrate,
wherein the dimension and the pitch are smaller in one of the first direction and the second direction than in the other.

8. The method according to claim 7, wherein the apparatus is configured to draw, on the substrate, a pattern on each of a straight line extending in the first direction, and a plurality of straight lines parallel with the straight line and arranged in the second direction at predetermined intervals.

9. A method of manufacturing an article, the method comprising:
performing drawing on a substrate using a drawing apparatus defined in claim 1;
developing the substrate on which the drawing has been performed; and
processing the developed substrate to manufacture the article.

10. A method of manufacturing an article, the method comprising:
performing drawing on a substrate using a drawing method defined in claim 7;
developing the substrate on which the drawing has been performed; and
processing the developed substrate to manufacture the article.
